(19) United States
(12) Patent Application Publication
(10) Pub. No.: US 2009/0184882 A1
(43) Pub. Date: Jul. 23, 2009

(54) Semiconductor package with an antenna and manufacture method thereof

(76) Inventor: En-Min Jow, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/153,739

(22) Filed: May 23, 2008

(30) Foreign Application Priority Data
Jan. 17, 2008 (TW) 97101763

(51) Int. Cl. H01Q 1/40; H01L 21/02

(52) U.S. Cl. 343/873; 438/127; 257/E21.002

(57) ABSTRACT

A manufacture method of semiconductor package with an antenna includes: providing a substrate with a first surface and an opposite second surface, wherein the first surface has a predetermined circuit; arranging a functional element on the first surface and electrically connecting the functional element with the predetermined circuit of the substrate; encapsulating the functional element and a portion of the first surface of the substrate by an encapsulating body; and printing an antenna electrically connected with the predetermined circuit on the surface of the encapsulating body. A semiconductor package with an antenna is also disclosed.

### BACKGROUND OF THE INVENTION

1. Field of the Invention

The present invention relates to a semiconductor package and its manufacture method, and more especially relates to integrate an antenna into the semiconductor package and its manufacture method.

2. Description of the Prior Art

Due to wireless communication technique can make the users to operate the electronic products freely without being limited by the wires, so that the electronic products with the wireless communication function, for example, Bluetooth, WiFi, WiMax and etc, are popular with the users. An antenna is one of major components for wireless communication technique, and the electronic products toward to the development with slim, compact and lightweight are inevitable trend, so how to arrange the antenna with the electronic products, particularly to the portable electronic products, is an important issue.

Conventional antenna is arranged on the surface of the circuit board. As a consequence, the size of the circuit board can not be further reduced. Another conventional antenna layout technique is to arrange the antenna in one of inner layers of the multi-layer circuit board such that the antenna does not occupy the surface of the circuit board to reserve a large space for arranging the chips thereon. However, the process of the multi-layer circuit board is complex so that the price of the multi-layer circuit board is more expensive, and the production cost of the electronic products can not further cut down.

To sum up, how to reduce the occupying area of the antenna on the circuit board and manufacture by a more convenience way to cut down the production cost is a goal needed to pursue until now.

### SUMMARY OF THE INVENTION

In view of above-mentioned problem, one object of present invention is to provide a semiconductor package with an antenna and its manufacture method, which prints the antenna on a surface of the semiconductor package to avoid the antenna occupying the area of the circuit board and to manufacture it by a more convenient way.

To achieve the purposes mentioned above; one embodiment of the present invention is to provide a manufacture method of semiconductor package with an antenna, which includes: providing a substrate with a first surface and an opposite second surface, wherein the first surface has a predetermined circuit; arranging a functional element on the first surface and electrically connecting the functional element to the predetermined circuit of the substrate; encapsulating the functional element and a portion of the first surface of substrate by an encapsulating body; and printing an antenna electrically connected with the predetermined circuit on a surface of the encapsulating body.

To achieve the purposes mentioned above, another embodiment of the present invention is to provide a semiconductor package with an antenna, which includes a substrate, a functional element, an encapsulating body and an antenna. The substrate has a first surface and an opposite second surface, wherein the first surface has a predetermined circuit. The functional element is arranged on the first surface and electrically connected with the predetermined circuit of the substrate. The encapsulating body encapsulates the functional element, and partially encapsulates the first surface of substrate. The antenna is arranged on the surface of the encapsulating body and electrically connected with the predetermined circuit.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1a is a cross-sectional diagram illustrating a semiconductor package with an antenna according to one preferred embodiment of present invention;

FIG. 1b is a top-view diagram illustrating a semiconductor package with an antenna according to one preferred embodiment of present invention;

FIG. 2 is cross-sectional diagram illustrating a semiconductor package with an antenna according to another preferred embodiment of present invention; and

FIG. 3a to FIG. 3f are schematic diagrams illustrating a manufacture method of semiconductor package with an antenna according to one preferred embodiment of present invention.

### DESCRIPTION OF THE PREFERRED EMBODIMENT

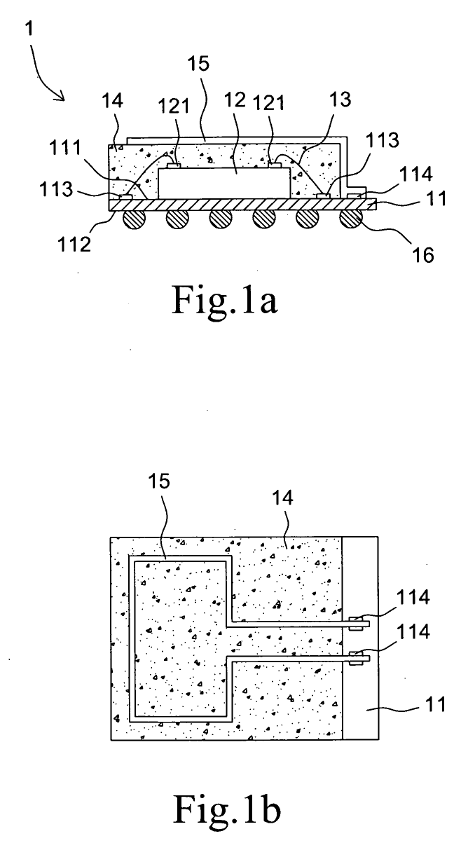

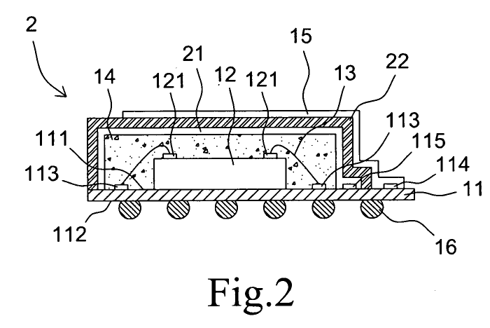

Please refer to FIG. 1a and FIG. 1b, are one of preferred embodiments illustrating a semiconductor package 1 with an antenna according to present invention, which includes a substrate 11, a functional element 12, an encapsulating body 14 and an antenna 15. The substrate 11 has a first surface 111 and an opposite second surface 112, wherein the first surface 111 has a predetermined circuit (not shown). In an exemplary embodiment, the predetermined circuit has a plurality of solder-pads 113, 114 to be a contact point for electrically connection. The functional element 12 is arranged on the first surface 111 of the substrate 11 and electrically connected to the predetermined circuit of the substrate 11.

Accordance to one embodiment of FIG. 1a, a plurality of solder-pads 121 on the functional element 12 and the solder-pads 113 of the predetermined circuit substrate 11 are connected by a plurality of wires 13 such that the functional element 12 and the predetermined circuit of the substrate 11 can realize the purpose of electrically connection. It is also not a limitation to confine the scope of the present invention, the functional element 12 can be electrically connected to the predetermined circuit of the substrate 11 by conductive bumps. In one embodiment, the functional element 12 is a RF chip or a wireless transceiver module, and the wireless transceiver module can be realized by the single chip or the multi-chip.

Accordingly, the encapsulating body 14 encapsulates the functional element 12 and encapsulates a portion of the first surface 111 of substrate 11. As FIG. 1a shown, the encapsulating body 14 partially encapsulates the first surface 111 to expose the solder-pads 114 as a contact point for electrically connection with the antenna 15 and the predetermined circuit.

A conductive liquid can be printed on the surface of the encapsulating body 14 to form the antenna 15 for electrically connection with the solder-pads 114 of the predetermined circuit of the substrate 11 according to the designed layout with an antennal pattern by inkjet printing. Thereby, the antenna 15 can be electrically connected with the functional element 12 or an exterior.

In a preferred embodiment, a semiconductor package 1 with an antenna of the present invention further includes a plurality of solder balls 16 arranged on the second surface 112 of the substrate 11 and electrically connected with the predetermined circuit. Therefore, the functional element 12 and the antenna 15 can be electrically connected to the exterior by the solder balls 16.

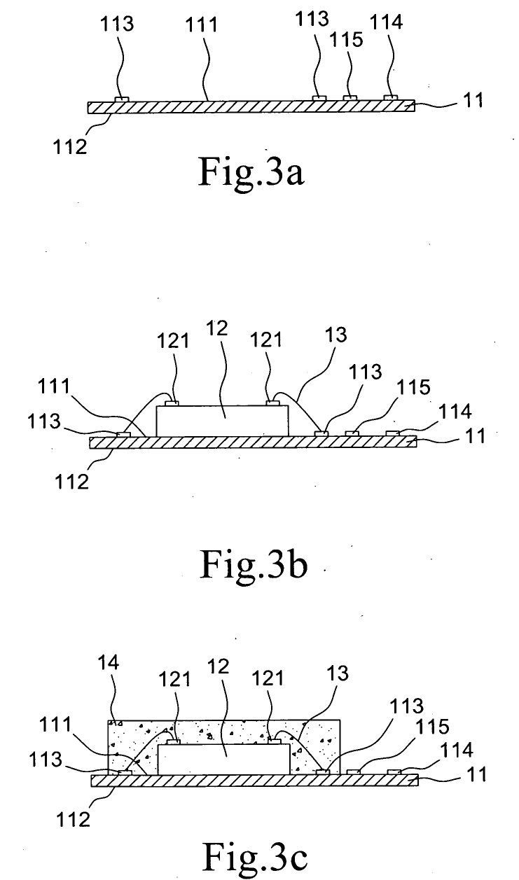

Please refer to FIG. 2, which illustrates a semiconductor package 2 with an antenna according to another preferred embodiment of the present invention. Comparing with the embodiment of the FIG. 1a, a major difference from an embodiment of the FIG. 2 is that an electromagnetic shielding layer 21 is arranged between the antenna 15 and the encapsulating body 14.

The electromagnetic shielding layer 21 is formed on the surface of the encapsulating body 14 and electrically connected with a solder-pad 115 of the predetermined circuit of the substrate 11. Thereby, the electromagnetic shielding layer 21 can achieve the electromagnetic shielding function by the predetermined circuit with the grounding design. Besides, an insulating layer 22 is arranged between the electromagnetic shielding layer 21 and the antenna 15 to avoid short-circuiting from the electromagnetic shielding layer 21 to the antenna 15.

According to exemplary embodiment of FIG. 2, the insulating layer 22 fully covers the electromagnetic shielding layer 21 to isolate the electromagnetic shielding layer 21 from the antenna 15. However, the foregoing embodiments would be modified to be another embodiment by a person having ordinary skill in the art. For example, the insulating layer 22 may be formed on a portion of the surface of the electromagnetic shielding layer 21 and arranged relatively to the position of the antenna 15. Notably, the above-mentioned electromagnetic shielding layer 21 can be formed on the surface of the encapsulating body 14 by inkjet printing.

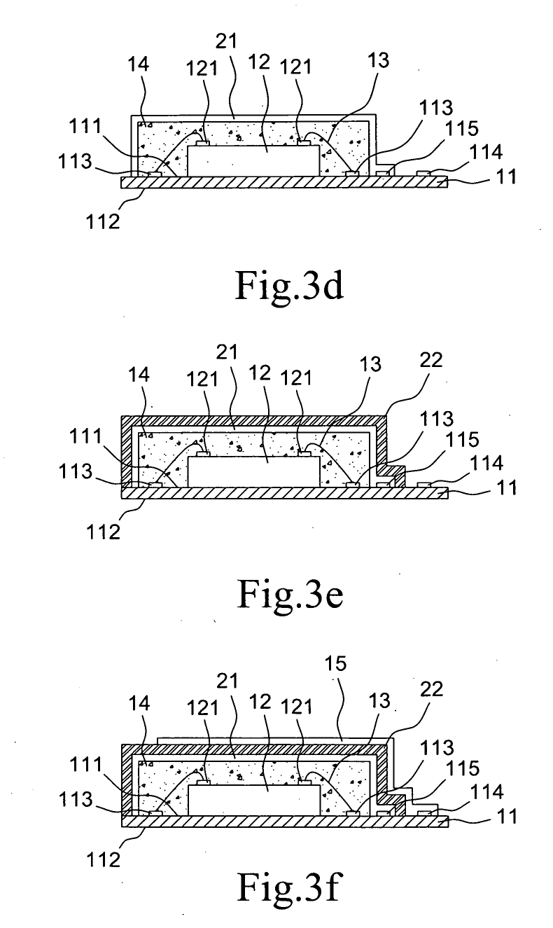

Please refer to FIG. 3a to FIG. 3f, which illustrate a manufacture method of semiconductor package with an antenna according to the embodiment of FIG. 2. Firstly, a substrate 11 is provided and it has a first surface 111 and an opposite second surface 112, wherein the first surface 111 has a predetermined circuit. In one embodiment, as FIG. 3a shown, the predetermined circuit includes a plurality of solder-pads 113,114,115. Please refer to the FIG. 3b, a functional element 12 is arranged on the first surface 111 of the substrate 11 and electrically connected with the solder-pads 113 of the substrate 11 by a proper method.

Please refer to the FIG. 3c, an encapsulating body 14 encapsulates the functional element 12 and partially encapsulates the first surface 111 of the substrate 11 to expose the solder-pads 114, 115. Please refer to FIG. 3d, a an electromagnetic shielding layer 21 is formed on the surface of the encapsulating body 14 and electrically connected with the solder-pads 115 for grounding connection to achieve electromagnetic shielding function by the printed conductive liquid.

As FIG. 3e shown, an insulating layer 22 is formed on the surface of the electromagnetic shielding layer 21 by a proper method. As FIG. 3f shown, an antenna 15 is formed on the surface of the insulating layer 22 and electrically connected with the solder-pads 114 by the printed conductive liquid according to the designed antenna layout. In one embodiment, the above-mentioned print technique may be an inkjet print technique. Finally, a plurality of solder balls 16 are formed on the second surface 112 of the substrate 11 to complete the embodiment, that shown in FIG. 2.

To sum up, the present invention provides a semiconductor package with an antenna and its manufacture method, which integrates the antenna onto the surface of the semiconductor package to avoid the antenna occupying the area of the circuit board without multi-layer circuit board. Besides, the antenna is formed on the surface of the semiconductor package directly by printing method without semiconductor process or additional steps, for example, chip antenna, to manufacture it by a more convenient way.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A manufacture method of semiconductor package with an antenna, comprising:
providing a substrate with a first surface and an opposite second surface, wherein the first surface has a predetermined circuit;
arranging a functional element on the first surface and electrically connecting the functional element to the predetermined circuit of the substrate;
encapsulating the functional element and a portion of the first surface of substrate by an encapsulating body; and
printing an antenna electrically connected with the predetermined circuit on a surface of the encapsulating body.

2. The manufacture method of semiconductor package with an antenna according to claim 1, wherein the antenna is formed on the surface of the encapsulating body by inkjet printing.

3. The manufacture method of semiconductor package with an antenna according to claim 1, further comprising:
printing an electromagnetic shielding layer electrically connected with the predetermined circuit on the surface of the encapsulating body; and
forming an insulating layer between the electromagnetic shielding layer and the antenna.

4. The manufacture method of semiconductor package with an antenna according to claim 3, wherein the electromagnetic shielding layer is formed on the surface of the encapsulating body by inkjet printing.

5. The manufacture method of semiconductor package with an antenna according to claim 1, wherein the functional element is a RF chip.

6. The manufacture method of semiconductor package with an antenna according to claim 1, wherein the functional element is a wireless transceiver module.

7. The manufacture method of semiconductor package with an antenna according to claim 1, wherein the functional element is electrically connected with the predetermined circuit by a wire or a conductive bump.

8. The manufacture method of semiconductor package with an antenna according to claim 1, further comprising:
forming a plurality of solder balls on the second surface of the substrate electrically connected with the predetermined circuit.

9. A semiconductor package with an antenna, comprising:
a substrate with a first surface and an opposite second surface, wherein the first surface has a predetermined circuit;
a functional element arranged on the first surface and electrically connected with the predetermined circuit of the substrate;
an encapsulating body encapsulating the functional element, and encapsulating a portion of the first surface of the substrate; and
an antenna arranged on a surface of the encapsulating body and electrically connected with the predetermined circuit.

10. The semiconductor package with an antenna according to claim 9, wherein the antenna is formed on the surface of the encapsulating body by inkjet printing.

11. The semiconductor package with an antenna according to claim 9, further comprising:
an electromagnetic shielding layer arranged on the surface of the encapsulating body and electrically connected with the predetermined circuit; and
an insulating layer arranged between the electromagnetic shielding layer and the antenna.

12. The semiconductor package with an antenna according to claim 11, wherein the electromagnetic shielding layer is formed on the surface of the encapsulating body by inkjet printing.

13. The semiconductor package with an antenna according to claim 9, wherein the functional element is a RF chip.

14. The semiconductor package with an antenna according to claim 9, wherein the functional element is a wireless transceiver module.

15. The semiconductor package with an antenna according to claim 9, wherein the functional element is electrically connected with the predetermined circuit by a wire or a conductive bump.

16. The semiconductor package with an antenna according to claim 9, further comprising a plurality of solder balls arranged on the second surface of the substrate and electrically connected with the predetermined circuit.
